(19) United States
(12) Patent Application Publication
(10) Pub. No.: US 2022/0415981 A1
(43) Pub. Date: Dec. 29, 2022

(54) ARRAY SUBSTRATE AND MANUFACTURING METHOD THEREOF, DISPLAY PANEL AND DISPLAY DEVICE

(71) Applicant: BOE Technology Group Co., Ltd., Beijing (CN)

(72) Inventors: Shi SHU, Beijing (CN); Chuanxiang XU, Beijing (CN); Haitao HUANG, Beijing (CN); Qi YAO, Beijing (CN); Tieshi WANG, Beijing (CN); Zhiqiang XU, Beijing (CN)

(21) Appl. No.: 17/777,808

(22) PCT Filed: Feb. 23, 2021
(86) PCT No.: PCT/CN2021/077437

§ 371 Date: May 18, 2022

(30) Foreign Application Priority Data
Feb. 27, 2020 (CN) 202010125182.0

(51) Int. Cl. H01L 27/32; H01L 51/52; H01L 51/56

(52) U.S. Cl. CPC H01L 27/3246; H01L 27/322; H01L 51/5284; H01L 51/56; H01L 2227/323

(57) ABSTRACT

The present disclosure provides an array substrate and a manufacturing method thereof, a display panel and a display device. The array substrate includes a base substrate; a pixel defining layer disposed on the base substrate, the pixel defining layer is provided with a plurality of opening areas, peripheral areas surrounding the opening areas and other areas except the opening areas and the peripheral areas; and a first electrode layer, disposed on the side of the pixel defining layer facing away from the base substrate. A roughness of a surface, facing away from the base substrate, of the first electrode layer in the peripheral regions is greater than a roughness of a surface, facing away from the base substrate, of the first electrode layer in the other regions.

### CROSS REFERENCE TO RELATED APPLICATIONS

The present disclosure is a National Stage of International Application No. PCT/CN2021/077437, filed Feb. 23, 2021, which claims priority from Chinese Patent Application No. 202010125182.0, filed with the China National Intellectual Property Administration, on Feb. 27, 2020 and entitled “ARRAY SUBSTRATE AND MANUFACTURING METHOD THEREOF, DISPLAY PANEL AND DISPLAY DEVICE”, the entire contents of which are incorporated herein by reference.

### FIELD

The present disclosure relates to the technical field of display, In some embodiments to an array substrate and manufacturing method thereof, display panel and display apparatus.

### BACKGROUND

With the development of display technology, people have an increasing demand for slimness and flexibility of display panels, which can be met by reducing a thickness of a module.

In the related art, a thickness of a circular polarizer in an array substrate accounts for a larger proportion of a thickness of the entire array substrate. In order to solve this problem, a color filter part is integrated on an encapsulation layer of a light emitting device, replacing the circular polarizer. As a result, the thickness of the module can be greatly reduced. However, for the above-mentioned structure of the array substrate, when external light is irradiated on a display panel in an off-screen state, since a cathode layer in each sub-pixel has a fixed reflection direction for the light irradiated thereon and the sub-pixels in different positions have a fixed reflection direction for the light irradiated thereon, the light reflected back is in a separated state, that is, a phenomenon of color separation of the reflected light occurs, which affects a user's experience of an absolutely black screen.

Therefore, how to solve the color separation problem of the display panel has become a technical problem to be solved by those of skill in the art.

### SUMMARY

In view of this, embodiments of the present disclosure provide an array substrate and a manufacturing method thereof, a display panel and a display apparatus, so as to solve a color separation problem of a display panel.

In a first aspect, an embodiment of the present disclosure provides an array substrate, including:

a base substrate;

a pixel defining layer, disposed on a side of the base substrate, the pixel defining layer is provided with opening regions, peripheral regions surrounding the opening regions and other regions except the opening regions and the peripheral regions;

a first electrode layer, disposed on a side, facing away from the base substrate, of the pixel defining layer, a roughness of a surface, facing away from the base substrate, of the first electrode layer in the peripheral regions is greater than a roughness of a surface, facing away from the base substrate, of the first electrode layer in the other regions; and

color filter parts, disposed on a side, facing away from the base substrate, of the first electrode layer, the color filter parts arranged in one-to-one correspondence to the opening regions, orthographic projections of the color filter parts on the base substrate cover orthographic projections of the opening regions on the base substrate, and the color filter parts are configured to filter incident light from outside to the color filter parts.

In some embodiments, the peripheral regions include slope regions connected with the opening regions and transition regions connected with the slope regions.

In some embodiments, a roughness of a surface, facing away from the base substrate, of the pixel defining layer in peripheral regions is greater than a roughness of a surface, facing away from the base substrate, of the pixel defining layer in the other regions; and

the roughness of the first electrode layer in the peripheral regions is approximately equal to the roughness of the surface of the pixel defining layer in the peripheral regions.

In some embodiments, for one of the opening regions, in a peripheral region surrounding an opening region, the pixel defining layer is provided with recessed parts surrounding the opening region;

the recessed parts are arranged in sequence in a direction in which the opening region points towards the peripheral region, and a distance between the recessed parts away from the opening region and the base substrate is larger than a distance between the recessed parts close to the opening region and the base substrate.

In some embodiments, for one of the opening regions, in a peripheral region surrounding an opening region, the pixel defining layer is provided with recessed parts surrounding the opening region;

the recessed parts are arranged in sequence in a direction in which the opening region points towards the peripheral region, and a distance between the recessed parts away from the opening region and the base substrate is equal to a distance between the recessed parts close to the opening region and the base substrate.

In some embodiments, a shape defined by orthographic projections of the recessed parts on the base substrate is same as a shape of an orthographic projection of the opening region on the base substrate.

In some embodiments, a central point of the shape defined by the orthographic projections of the recessed parts on the base substrate roughly overlaps with a central point of the orthographic projection of the opening region on the base substrate.

In some embodiments, a width of the recessed parts, in the direction in which the opening region points towards the peripheral region, ranges from 0.5 μm to 2.5 μm; and

a distance between adjacent recessed parts ranges from 0.5 μm to 2.5 μm.

In some embodiments, a distance between an upper surface of each of the recessed parts and a lower surface of each of the recessed parts ranges from 0.2 μm to 1.0 μm.

In some embodiments, each of the recessed parts includes a plurality of sub recessed parts, and adjacent sub recessed parts are arranged at interval by a preset distance; and

a shape defined by orthographic projections of the sub recessed parts on the base substrate is same as a shape of an orthographic projection of the opening region on the base substrate.

In some embodiments, the shape defined by the orthographic projections of the sub recessed parts on the base substrate is a circle, a rectangle and an oval.

In some embodiments, the preset distance ranges from 0.5 μm to 2.5 μm.

In some embodiments, the array substrate further includes a black matrix;

the black matrix surrounds at least one of the color filter parts; and

for one of the opening regions, an orthographic projection of a peripheral region on the base substrate has an overlapping region with an orthographic projection of the black matrix on the base substrate, and the orthographic projection of the peripheral region on the base substrate has an overlapping region with an orthographic projection of a color filter part on the base substrate.

In some embodiments, a distance between a boundary of each of peripheral regions away from the opening regions and a boundary of the opening region ranges from 6 μm to 10 μm.

In some embodiments, the array substrate further includes:

a second electrode layer, arranged between the base substrate and the pixel defining layer, an orthographic projection of the second electrode layer on the base substrate covers the orthographic projections of the opening regions on the base substrate; and

a light emitting layer, arranged between the first electrode layer and the second electrode layer, an orthographic projection of the light emitting layer on the base substrate covers the orthographic projections of the opening regions on the base substrate.

An embodiment of the present disclosure further provides a manufacturing method of the array substrate according to embodiments of the present disclosure, including:

providing a base substrate;

forming a pixel defining layer on the base substrate;

performing composition on the pixel defining layer, so that a plurality of opening regions, peripheral regions surrounding opening regions and other regions except the opening regions and the peripheral regions are formed in the pixel defining layer;

forming a first electrode layer on the pixel defining layer, a roughness of a surface, facing away from the base substrate, of the first electrode layer in the peripheral regions is greater than a roughness of a surface, facing away from the base substrate, of the first electrode layer in the other regions; and

forming color filter parts on the first electrode layer.

In some embodiments, the performing composition on the pixel defining layer specifically includes:

forming photoresist on the pixel defining layer; and

performing exposure development on the pixel defining layer by using a preset mask, to form the opening regions and patterns of the pixel defining layer in the peripheral regions, the preset mask comprises patterns of the opening regions and patterns of recessed parts.

In some embodiments, after forming the first electrode layer on the pixel defining layer and before forming the color filter parts on the first electrode layer is formed, the manufacturing method further includes:

forming a black matrix on the first electrode layer.

An embodiment of the present disclosure further provides a display panel, including the array substrate provided by embodiments of the present disclosure.

An embodiment of the present disclosure further provides a display apparatus, including the display panel provided by embodiments of the present disclosure.

### BRIEF DESCRIPTION OF THE DRAWINGS

FIG. 1 is a schematic structural diagram of an array substrate in the related art.

FIG. 2 is a schematic structural diagram of an array substrate provided by an embodiment of the present disclosure.

FIG. 3 is a schematic sectional structural diagram of a pixel defining layer provided by an embodiment of the present disclosure.

FIG. 4A is a schematic top-viewed structural diagram of a pixel defining layer provided by an embodiment of the present disclosure.

FIG. 4B is a schematic top-viewed structural diagram of an array substrate provided by an embodiment of the present disclosure.

FIG. 5 is another schematic top-viewed structural diagram of a pixel defining layer provided by an embodiment of the present disclosure.

FIG. 6 is further another schematic top-viewed structural diagram of a pixel defining layer provided by an embodiment of the present disclosure.

FIG. 7 is a schematic top-viewed structural diagram of an entire pixel defining layer provided by an embodiment of the present disclosure.

FIG. 8 is a schematic structural diagram of a display panel provided by an embodiment of the present disclosure.

### DETAILED DESCRIPTION OF THE EMBODIMENTS

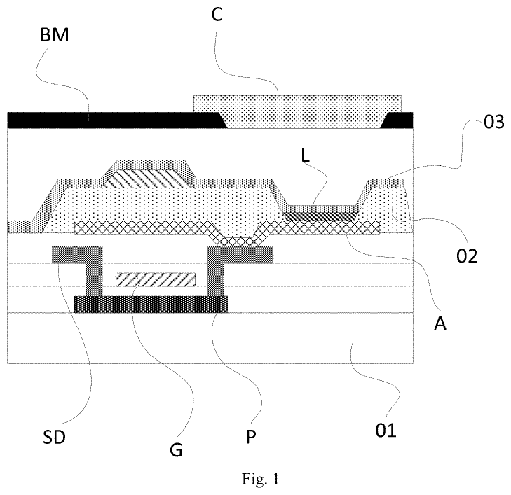

A structure of an array substrate in the related art is as shown in FIG. 1, including: a base substrate 01, a pixel driving circuit (including a semiconductor layer P, a gate layer G and a source-drain electrode layer SD) disposed on the base substrate 01, an anode layer A electrically connected with the pixel driving circuit, and a pixel defining layer 02 disposed on the anode layer A. The pixel defining layer 02 has an opening region, a light emitting layer L is in the opening region, a cathode layer 03 covers the pixel defining layer 02 and the opening region as a whole, a black matrix layer BM and color filter parts C are further arranged on a side of the cathode layer 03 facing away from the base substrate 01, and the color filter parts C are arranged in one-to-one correspondence to the opening regions. With regard to the structure of the array substrate shown in FIG. 1, because no circular polarizer is arranged, under an off-screen state, when external light is irradiated on a display panel, the light is irradiated on the cathode layer 03 through the color filter parts C, and the cathode layer 03 reflects the external light; and because of shapes and structural design of sub-pixels, light reflected by the sub-pixels will exit along a fixed direction and the emergent light corresponds to colors of the sub-pixels, resulting in that the light reflected by the sub-pixels at different locations is not well mixed and light of different colors is separated and cannot be well mixed into white light. Such a regular color separation phenomenon is prone to being observed by human eyes, which affects a user's experience of an absolutely black screen.

Based on the above problem existing in the array substrate in the related art, embodiments of the present disclosure provide an array substrate and a manufacturing method thereof, a display panel and a display apparatus. In order to make objectives, technical solutions and advantages of the present disclosure clearer, implementations of the array substrate and the manufacturing method thereof, the display panel and the display apparatus provided by embodiments of the present disclosure will be further described in detail below in combination with the accompanying drawings. It should be understood that the preferred embodiments described below are only used to illustrate and explain the present disclosure, but are not to limit the present disclosure. Embodiments in the present application and the features in embodiments may be combined with each other without conflict.

Shapes and dimensions of components in the accompanying drawings do not reflect a real scale, and are only intended to illustrate the present disclosure.

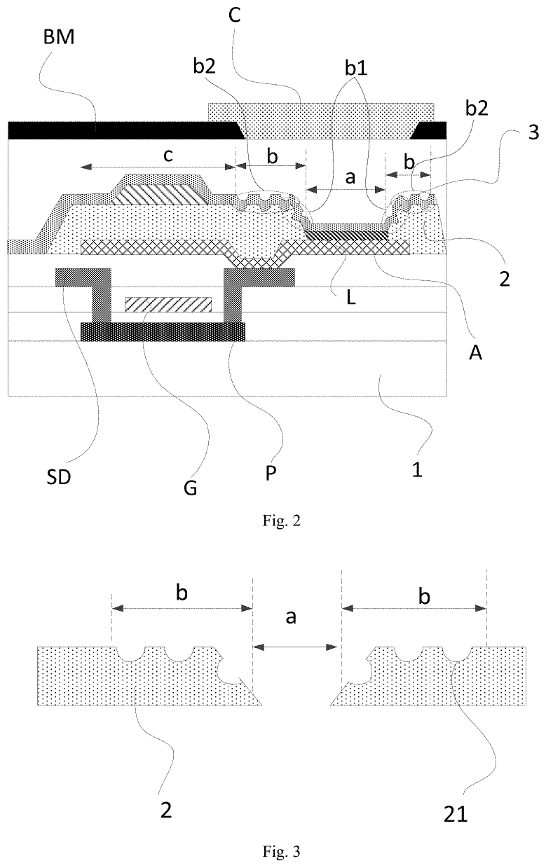

In some embodiments, an embodiment of the present disclosure provides an array substrate. As shown in FIG. 2, the array substrate includes:

a base substrate 1;

a pixel defining layer 2, disposed on a side of the base substrate 1, where the pixel defining layer 2 is provided with a plurality of opening regions a, peripheral regions b surrounding the opening regions a and other regions c except the opening regions a and the peripheral regions b;

a first electrode layer 3, disposed on a side, facing away from the base substrate 1, of the pixel defining layer 2, where a roughness of a surface, facing away from the base substrate 1, of the first electrode layer 3 in the peripheral regions b is greater than a roughness of a surface, facing away from the base substrate 1, of the first electrode layer 3 in the other regions; and

color filter parts C, disposed on a side, facing away from the base substrate 1, of the first electrode layer 3, and the color filter parts C arranged in one-to-one correspondence to the opening regions a; orthographic projections of the color filter parts C on the base substrate 1 cover orthographic projections of the opening regions a on the base substrate 1, and the color filter parts C are configured to filter incident light from outside to the color filter parts C.

For example, the color filter parts C may be red color filter parts filtering red light, or green color filter parts filtering green light, or blue color filter parts filtering blue light; and the color filter parts C corresponding to different opening regions a may filter light of different colors.

In some embodiments, by arranging the roughness of the first electrode layer in the peripheral regions to be larger than the roughness thereof in the other regions, external light reflected by the first electrode layer in a certain direction is reduced, and light irradiated on the first electrode layer in the peripheral regions is subjected to diffuse reflection, i.e. reflected directions of the light are changed, so the emergent light emits from more directions; and therefore, emergent light from adjacent sub-pixels in different directions can be sufficiently mixed to form white light, thereby reducing the color separation phenomenon occurring in the array substrate in the related art.

It should be noted that, in the array substrate provided by embodiments of the present disclosure, the proposed opening regions are effective light emitting regions of the sub-pixels, and the peripheral region corresponding to each opening region refers to a region closely adjacent to a boundary of the opening region and surrounds the opening region by a preset distance. The preset distance needs to be set according to a region covered by a black matrix. That is, light can be irradiated on the first electrode layer through the color filter parts, and regions where the light reflected by the first electrode layer can be emitted through the color filter parts are all within ranges of the peripheral regions. Normally, it needs to be ensured that orthographic projections of the peripheral regions on the base substrate have overlapping regions with an orthographic projection of the black matrix on the base substrate and with orthographic projections of the color filter parts on the base substrate.

In some embodiments, as shown in FIG. 2, the array substrate further includes the black matrix BM and the black matrix BM surrounds at least one of the color filter parts C. For to one of the opening regions a, an orthographic projection of a corresponding peripheral region b on the base substrate 1 has an overlapping region with an orthographic projection of the black matrix BM on the base substrate 1, and the orthographic projection of the peripheral region b on the base substrate 1 has an overlapping region with the orthographic projection of the corresponding color filter part C on the base substrate 1.

In order to ensure light used by the sub-pixels for display can be evenly emitted, the first electrode layer in the opening regions needs to be maintained flat. In the meantime, it should be ensured that the first electrode layer in the other regions in addition to the peripheral regions is flat. That is, large-range unevenness of first electrodes is avoided in order to effectively reduce resistance of the first electrodes, so as to avoid display failure caused by excessively large resistance.

It should be noted that FIG. 1 is illustrated by taking the orthographic projection of the black matrix BM on the base substrate having an overlapping region with the orthographic projections of the color filter parts on the base substrate, which is not limited here. The orthographic projection of the black matrix BM on the base substrate may be non-overlapping with the orthographic projections of the color filter parts on the base substrate, i.e. boundaries of the color filter parts completely overlap with a boundary of the black matrix. A relative position relation between the black matrix and the color filter parts may be selected according to actual condition, which is not limited here.

In some embodiments, as shown in FIG. 2, the peripheral regions b include slope regions b1 connected with the opening regions a and transition regions b2 connected with the slope regions b1.

In some embodiments, as shown in FIG. 1 and FIG. 2, a roughness of a surface of the pixel defining layer 2 facing away from the base substrate 1 in peripheral regions b is greater than a roughness of a surface of the pixel defining layer 2 facing away from the base substrate 1 in the other regions;

the roughness of the first electrode layer 3 in the peripheral regions b is approximately equal to the roughness of the surface of the pixel defining layer 2 in the peripheral regions b.

In some embodiments, the first electrode layer is often a metal electrode, and in order to ensure that the light used by the sub-pixels for display can be emitted through the first electrode layer, the first electrode layer needs to be arranged to be a translucent and semi-reflective electrode with a relatively small thickness, resulting in certain difficulty in changing its roughness through direct composition. Therefore, composition may be performed through the pixel defining layer which is located below the first electrode layer and is directly adjacent to the first electrode layer so as to change the roughness of the surface of the pixel defining layer, so that when the first electrode layer is formed on the pixel defining layer, the roughness of the first electrode layer is approximately equal to the roughness of the surface of the pixel defining layer, thereby lowering difficulty of a manufacturing process. In some embodiments, due to actual process errors, it is relatively difficult to ensure that the roughness of the first electrode layer is strictly equal to the roughness of the surface of the pixel defining layer, so making the roughness of the first electrode layer to be equal to the roughness of the surface of the pixel defining layer may be understood as making the roughness of the first electrode layer approximately equal to the roughness of the surface of the pixel defining layer.

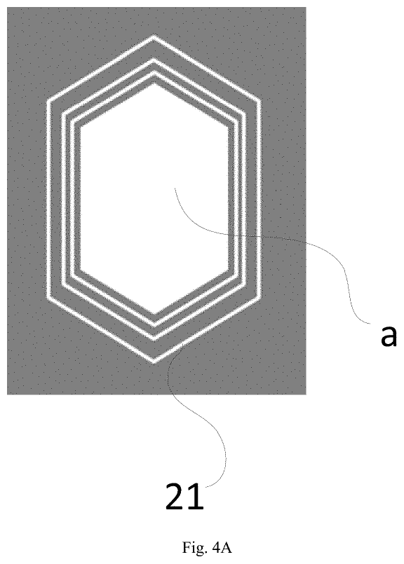

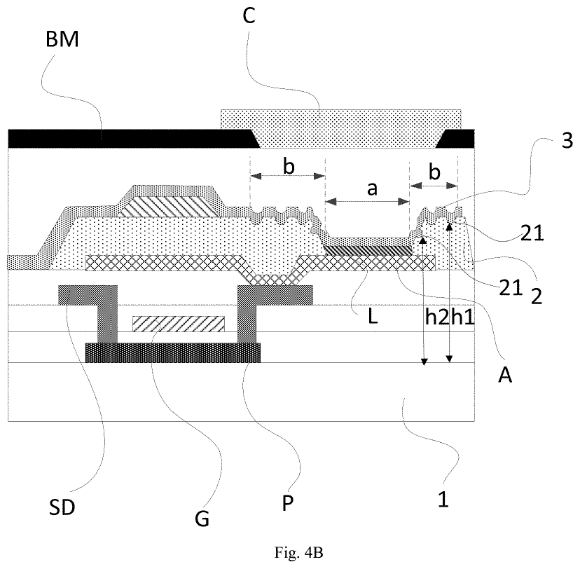

In some embodiments, as shown in FIG. 3 and FIG. 4A, for one of the opening regions a, in a peripheral region b surrounding an opening region a, the pixel defining layer 2 is provided with a plurality of recessed parts 21 surrounding the opening region a;

the recessed parts 21 are arranged in sequence in a direction in which the opening region a points towards the peripheral region b, and a distance between the recessed parts 21 away from the opening region a and the base substrate 1 is larger than or equal to a distance between the recessed parts 21 close to the opening region a and the base substrate 1.

For example, as shown in FIG. 4B, on a right side of the opening region a, in the direction in which the opening region a points towards the peripheral region b, the distance h2 between the recessed parts 21 relatively close to the opening region a and the base substrate 1 is larger than the distance h1 between the recessed parts 21 relatively away from the opening region a and the base substrate 1.

In some embodiments, the plurality of recessed parts may be formed on the surface of the pixel defining layer in the peripheral region, so as to change the roughness of the pixel defining layer in the peripheral region. Depths of the recessed parts may be set to be equal. Because the pixel defining layer includes a slope transition region and a flat region in the peripheral region, a distance between the recessed parts located in the slope transition region and the base substrate is smaller than a distance between the recessed parts located in the flat region and the base substrate.

The depths of the recessed parts should not be set to be excessively large, because excessively large depths will cause a situation that the first electrode layer is prone to short circuit, or that resistance of the first electrode layer is excessively large. The depths of the recessed parts may be set to be 0.2 μm-1.0 μm, i.e. a distance between an upper surface of each of the recessed parts and a lower surface of each of the recessed parts ranges from 0.2 μm to 1.0 μm. In some embodiments, 0.5 μm or 0.8 μm may be selected according to actual needs, which is not specifically limited here.

In some embodiments, as shown in FIG. 4A, a shape defined by orthographic projections of the recessed parts 21 on the base substrate 1 is same as a shape of the orthographic projection of the opening region a on the base substrate 1.

In some embodiments, the shape of the orthographic projections of the recessed parts on the base substrate may be set to be the same as the shape of the orthographic projection of the opening region on the base substrate. For example, the opening region is hexagonal, the shape defined by the orthographic projections of the recessed parts on the base substrate may be set to be hexagonal, so that an area of the peripheral region may be utilized to the greatest extent and more recessed parts may be arranged in the peripheral region, so as to increase the roughness of the pixel defining layer in the peripheral region. Of course, the shape defined by the orthographic projections of the recessed parts on the base substrate may also be set to be different from the shape of the orthographic projection of the opening region on the base substrate, which may be selected according to actual needs and is not limited here.

In some embodiments, as shown in FIG. 4A, a central point of the shape defined by the orthographic projections of the recessed parts 21 on the base substrate 1 roughly overlaps with a central point of the orthographic projection of the opening region a on the base substrate 1. In some embodiments, due to actual process errors, it is relatively difficult to ensure that the central point of the shape defined by the orthographic projections of the recessed parts 21 on the base substrate 1 strictly overlaps with the central point of the orthographic projection of the opening region a on the base substrate 1, so making the central point of the shape defined by the orthographic projections of the recessed parts 21 on the base substrate 1 to overlap with the central point of the orthographic projection of the opening region a on the base substrate 1 may be understood as making the central point of the shape defined by the orthographic projections of the recessed parts 21 on the base substrate 1 to roughly overlap with the central point of the orthographic projection of the opening region a on the base substrate 1.

In some embodiments, the central point of the shape defined by the orthographic projections of the recessed parts on the base substrate and the central point of the orthographic projection of the opening region on the base substrate are set to be the same central point, so positions in the peripheral regions at equal distances from the central point are the same in roughness. Therefore, it may be ensured that directions of light reflected different positions in the peripheral regions are changed, so as to increase emission directions of the reflected light.

In some embodiments, a width of the recessed parts, in the direction in which the opening region points towards the peripheral region, ranges from 0.5 μm to 2.5 μm; and

a distance between adjacent recessed parts ranges from 0.5 μm to 2.5 μm.

In some embodiments, in order to avoid the situation that the surface of the pixel defining layer is excessively rough, the resistance of the first electrode layer is increased and display quality is affected, the recessed parts need to be spaced by a certain distance so that the first electrode layer formed on the pixel defining layer can form a smooth wavy structure. The width of the recessed parts and spacing between the recessed parts may be set to be 0.5 μm-2.5 μm, for example, 0.8 μm or 1.5 μm. Of course, a specific value may be selected according to actual needs, which is not limited here.

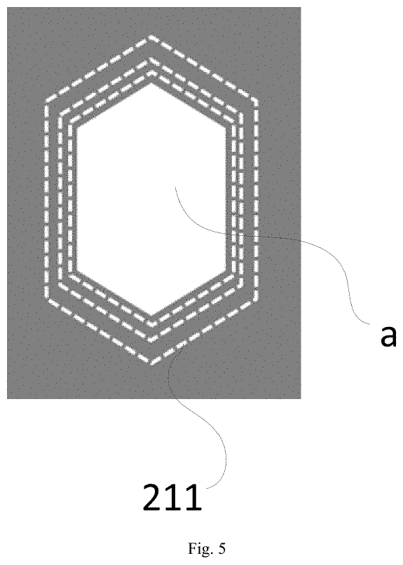

In some embodiments, as shown in FIG. 5, each of the recessed part includes a plurality of sub recessed parts 211, and adjacent sub recessed parts 211 are arranged at interval by a preset distance;

a shape defined by orthographic projections of all sub recessed parts 211 on the base substrate 1 is same as the shape of the orthographic projection of the opening region a on the base substrate 1.

In some embodiments, in order to further increase the roughness of the pixel defining layer in the peripheral regions, structures of the recessed parts may be further designed, i.e. the recessed parts are set to include the plurality of sub recessed parts and the adjacent sub recessed parts are arranged at interval by the preset distance. Through the arrangement, a wavy shape can be formed on the surface of the pixel defining layer in the direction in which the opening region points to the peripheral region, and a wavy shape can also be formed in a trend of a shape defined by each recessed part, so the emission directions of the reflected light may be further increased.

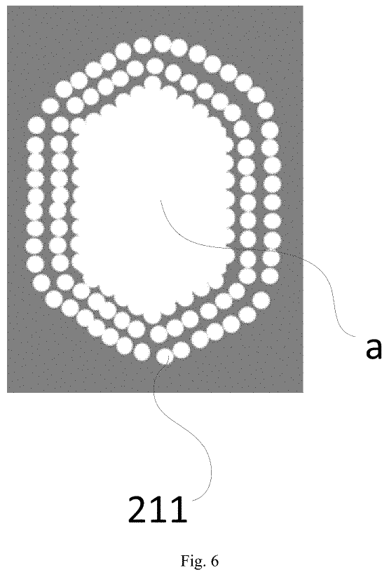

In some embodiments, as shown in FIG. 5 and FIG. 6, the shape defined by the orthographic projections of the sub recessed parts 211 on the base substrate 1 is a circle, a rectangle or an oval.

In some embodiments, in order to facilitate composition, the sub recessed parts may be set to be in the same shape. Of course, they may be set to be in different shapes based on needs, which may be circle, rectangle or any polygon. No limitation is made here.

A distance between adjacent sub recessed parts may range from 0.5 μm to 2.5 μm. In some embodiments, a dimension of one sub recessed part may be set to be equal to a dimension of an adjacent sub recessed part, which may increase evenness of the shape formed, is conducive to smooth transition of the first electrode layer formed subsequently, and avoids a short circuit problem.

In some embodiments, a distance between a boundary of each of peripheral regions away from the opening regions and a boundary of the opening region ranges from 6 μm to 10 μm.

In some embodiments, in the direction in which the opening region points to the peripheral region, a value range of a width of the peripheral region may be 6 μm-10 μm. The width is set according to a distance between a boundary of an opening of the black matrix and the boundary of the opening region, i.e. the distance between the boundary of the opening of the black matrix and the boundary of the opening region is generally 6 μm-10 μm. When the peripheral region is set, the distance between the boundary of the side of the peripheral region away from the opening region and the opening region may be larger than or equal to the distance between the boundary of the opening of the black matrix and the boundary of the opening region. A specific value of the distance may be selected according to actual application conditions, which is not specifically limited here.

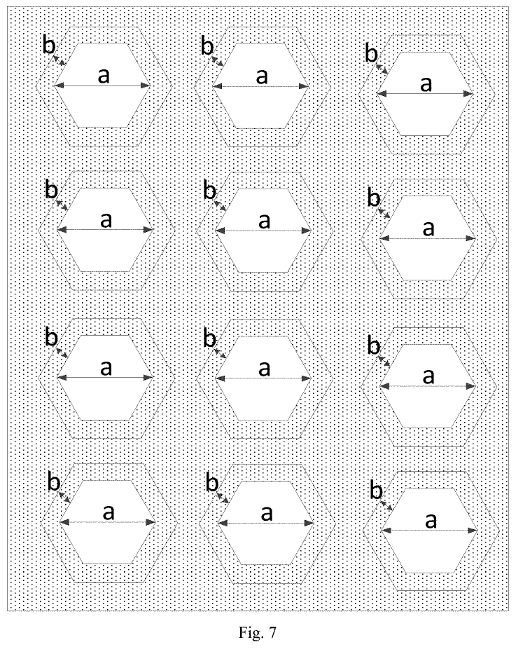

It should be noted that, in the array substrate provided by embodiments of the present disclosure, as shown in FIG. 7, besides the opening regions a and the peripheral regions b surrounding the opening regions a, the pixel defining layer further includes the other regions, such as a gap region between two adjacent peripheral regions b. In order to illustrate relative position relationships among the opening regions a, the peripheral regions b and the other regions, FIG. 7 does not illustrate a specific structure in each of the regions. For specific structure design in the peripheral regions b, reference may be made to structures shown in FIGS. 4A-6, which is not repeated here.

In some embodiments, as shown in FIG. 2, the array substrate further includes: a second electrode layer A arranged between the base substrate 1 and the pixel defining layer 2, where an orthographic projection of the second electrode layer A on the base substrate 1 covers the orthographic projections of the opening regions a on the base substrate 1; and

a light emitting layer L arranged between the first electrode layer 3 and the second electrode layer A, where an orthographic projection of the light emitting layer L on the base substrate 1 covers the orthographic projections of the opening regions a on the base substrate 1.

In some embodiments, parts of the second electrode layer corresponding to the opening regions are partitioned, and are connected to corresponding pixel driving circuits which dive the light emitting layer to emit light in cooperation with voltage applied by the second electrode layer and the first electrode layer. Because the color filter parts are arranged on the array substrate of the present disclosure, the light emitting layer provided by the embodiment of the present disclosure may all emit white light, or parts of the light emitting layer corresponding to the opening regions may emit light corresponding to the color filter parts, which may be selected according to actual needs and is not specifically limited here.

Based on the same inventive concept, an embodiment of the present disclosure further provides a manufacturing method of an array substrate, including:

a base substrate is provided;

a pixel defining layer is formed on the base substrate;

composition is performed on the pixel defining layer, so that a plurality of opening regions, peripheral regions surrounding opening regions and other regions except the opening regions and the peripheral regions are formed in the pixel defining layer;

a first electrode layer is formed on the pixel defining layer, where a roughness of a surface of the first electrode layer facing away from the base substrate in the peripheral regions is greater than a roughness of a surface of the first electrode layer facing away from the base substrate in the other regions; and

color filter parts are formed the first electrode layer.

In some embodiments, the performing composition on the pixel defining layer may include:

photoresist is formed on the pixel defining layer; and

exposure development is performed on the pixel defining layer by using a preset mask, to form the opening regions and patterns of the pixel defining layer in the peripheral regions, where the preset mask includes patterns of the opening regions and patterns of recessed parts.

In some embodiments, after forming the first electrode layer on the pixel defining layer and before forming the color filter parts on the first electrode layer, the manufacturing method further includes: a black matrix is formed the first electrode layer.

The manufacturing method of the array substrate has all advantages of embodiments of the above array substrate, functions and relative position relations of the film layers of the array substrate have been described in detail in the above embodiments, and reference may be made to the above embodiment for implementation, which is not repeated here.

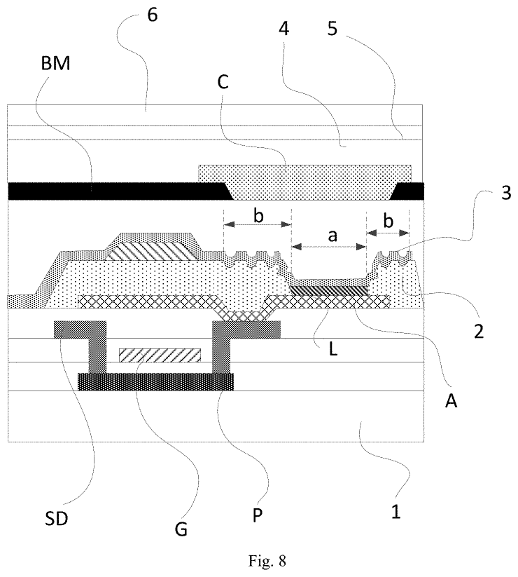

Based on the same inventive concept, an embodiment of the present disclosure further provides a display panel, as shown in FIG. 8. The display panel includes the array substrate provided by any one of the above embodiments, and further includes an encapsulation layer 4, an optical cement layer 5 and a protective cover plate 6 which are sequentially arranged on a side of a color filter part C facing away from a base substrate 1.

The display panel has all advantages of embodiments of the above array substrate, functions and relative position relations of the film layers of the array substrate have been described in detail in the above embodiments, and reference may be made to the above embodiments for implementation, which will be not repeated here.

Based on the same inventive concept, an embodiment of the present disclosure further provides a display apparatus, including the above display panel provided by embodiments of the present disclosure. The display apparatus may be: a mobile phone, a tablet computer, a television, a display, a notebook computer, a digital photo frame, a navigator or any other product or component with a display function. Other essential components of the display apparatus should be understood by those of ordinary skill in the art, and will not be repeated here, nor should it be regarded as a limitation of the present disclosure. For implementation of the display apparatus, reference may be made to the above-mentioned embodiments of the display panel, which will be not repeated here.

Embodiments of the present disclosure provide an array substrate and a manufacturing method thereof, a display panel and a display apparatus. The array substrate includes: the base substrate, and the pixel defining layer disposed on the base substrate, the pixel defining layer having the plurality of opening regions and the peripheral regions surrounding the opening regions; further includes: the first electrode layer disposed on the side of the pixel defining layer facing away from the base substrate; and further includes: the color filter parts disposed on the side of the first electrode layer facing away from the base substrate and arranged in one-to-one correspondence to the opening regions, as well as the black matrix surrounding each of the color filter parts. The orthographic projections of the color filter parts on the base substrate cover the orthographic projections of the opening regions on the base substrate, and the color filter parts are configured to filter the incident light from the outside. For one of the opening regions, the orthographic projection of the peripheral region on the base substrate has the overlapping region with the orthographic projection of the black matrix on the base substrate and with the orthographic projection of the color filter part on the base substrate. The roughness of the first electrode layer in the peripheral regions is larger than the roughness of the first electrode layer in the other regions. According to the present disclosure, by making the roughness of the first electrode layer in the peripheral regions to be larger than the roughness of the first electrode layer in the other regions, the external light irradiated on the first electrode layer in the peripheral regions is reflected in different directions, i.e. the original light reflection directions are changed by designing the roughness of the first electrode layer in the peripheral regions. Because the light reflected by the first electrode layer is reflected in different directions, the reflected light corresponding to the sub-pixels of different colors may be evenly mixed. Therefore, the color separation phenomenon of the display panel is reduced and the user's experience of the absolutely black screen is improved.

Obviously, those of skill in the art can make various changes and modifications to the present disclosure without departing from the spirit and scope of the present disclosure. Thus, provided that these changes and modifications of the present disclosure fall within the scope of the claims of the present disclosure and their equivalents, the present disclosure is also intended to cover such changes and modifications.

1. An array substrate, comprising:
a base substrate;
a pixel defining layer, disposed on a side of the base substrate, wherein the pixel defining layer is provided with opening regions, peripheral regions surrounding the opening regions and other regions except the opening regions and the peripheral regions;
a first electrode layer, disposed on a side, facing away from the base substrate, of the pixel defining layer, wherein a roughness of a surface, facing away from the base substrate, of the first electrode layer in the peripheral regions is greater than a roughness of a surface, facing away from the base substrate, of the first electrode layer in the other regions; and
color filter parts, disposed on a side, facing away from the base substrate, of the first electrode layer, wherein the color filter parts arranged in one-to-one correspondence to the opening regions, orthographic projections of the color filter parts on the base substrate cover orthographic projections of the opening regions on the base substrate, and the color filter parts are configured to filter incident light from outside to the color filter parts.

2. The array substrate according to claim 1, wherein the peripheral regions comprise slope regions connected with the opening regions and transition regions connected with the slope regions.

3. The array substrate according to claim 1, wherein a roughness of a surface, facing away from the base substrate, of the pixel defining layer in peripheral regions is greater than a roughness of a surface, facing away from the base substrate, of the pixel defining layer in the other regions; and
the roughness of the first electrode layer in the peripheral regions is approximately equal to the roughness of the surface of the pixel defining layer in the peripheral regions.

4. The array substrate according to claim 3, wherein for one of the opening regions, in a peripheral region surrounding an opening region, the pixel defining layer is provided with recessed parts surrounding the opening region, wherein
the recessed parts are arranged in sequence in a direction in which the opening region points towards the peripheral region, and a distance between the recessed parts away from the opening region and the base substrate is larger than a distance between the recessed parts close to the opening region and the base substrate.

5. The array substrate according to claim 3, wherein for one of the opening regions, in a peripheral region surrounding an opening region, the pixel defining layer is provided with recessed parts surrounding the opening region, wherein
the recessed parts are arranged in sequence in a direction in which the opening region points towards the peripheral region, and a distance between the recessed parts away from the opening region and the base substrate is equal to a distance between the recessed parts close to the opening region and the base substrate.

6. The array substrate according to claim 4 or 5, wherein a shape defined by orthographic projections of the recessed parts on the base substrate is same as a shape of an orthographic projection of the opening region on the base substrate.

7. The array substrate according to claim 6, wherein a central point of the shape defined by the orthographic projections of the recessed parts on the base substrate roughly overlaps with a central point of the orthographic projection of the opening region on the base substrate.

8. The array substrate according to claim 4, wherein a width of the recessed parts, in the direction in which the opening region points towards the peripheral region, ranges from 0.5 μm to 2.5 μm; and
a distance between adjacent recessed parts ranges from 0.5 μm to 2.5 μm.

9. The array substrate according to claim 4, wherein a distance between an upper surface of each of the recessed parts and a lower surface of each of the recessed parts ranges from 0.2 μm to 1.0 μm.

10. The array substrate according to claim 4, wherein each of the recessed parts comprises a plurality of sub recessed parts, and adjacent sub recessed parts are arranged at interval by a preset distance; and
a shape defined by orthographic projections of the sub recessed parts on the base substrate is same as a shape of an orthographic projection of the opening region on the base substrate.

11. The array substrate according to claim 10, wherein the shape defined by the orthographic projections of the sub recessed parts on the base substrate is a circle, a rectangle or an oval.

12. The array substrate according to claim 10, wherein the preset distance ranges from 0.5 μm to 2.5 μm.

13. The array substrate according to claim 1, further comprising a black matrix; wherein
the black matrix surrounds at least one of the color filter parts; and
for one of the opening regions, an orthographic projection of a peripheral region on the base substrate has an overlapping region with an orthographic projection of the black matrix on the base substrate, and the orthographic projection of the peripheral region on the base substrate has an overlapping region with an orthographic projection of a color filter part on the base substrate.

14. The array substrate according to claim 1, wherein a distance between a boundary of each of peripheral regions away from the opening regions and a boundary of the opening region ranges from 6 μm to 10 μm.

15. The array substrate according to claim 1, further comprising:
a second electrode layer, arranged between the base substrate and the pixel defining layer, wherein an orthographic projection of the second electrode layer on the base substrate covers the orthographic projections of the opening regions on the base substrate; and
a light emitting layer, arranged between the first electrode layer and the second electrode layer, wherein an orthographic projection of the light emitting layer on the base substrate covers the orthographic projections of the opening regions on the base substrate.

16. A manufacturing method of the array substrate according to claim 1, comprising:
providing a base substrate;
forming a pixel defining layer on the base substrate;
performing composition on the pixel defining layer, so that a plurality of opening regions, peripheral regions surrounding opening regions and other regions except the opening regions and the peripheral regions are formed in the pixel defining layer;
forming a first electrode layer on the pixel defining layer, wherein a roughness of a surface, facing away from the base substrate, of the first electrode layer in the peripheral regions is greater than a roughness of a surface, facing away from the base substrate, of the first electrode layer in the other regions; and
forming color filter parts on the first electrode layer.

17. The manufacturing method of the array substrate according to claim 16, wherein the performing composition on the pixel defining layer, comprises:
forming photoresist on the pixel defining layer; and
performing exposure development on the pixel defining layer by using a preset mask, to form the opening regions and patterns of the pixel defining layer in the peripheral regions, wherein the preset mask comprises patterns of the opening regions and patterns of recessed parts.

18. The manufacturing method of the array substrate according to claim 16, wherein after forming the first electrode layer on the pixel defining layer and before forming the color filter parts on the first electrode layer, the manufacturing method further comprises:
forming a black matrix on the first electrode layer.

19. A display panel, comprising the array substrate according to claim 1.

20. A display apparatus, comprising the display panel according to claim 19.
